(19) United States
(12) Patent Application Publication
(10) Pub. No.: US 2021/0111708 A1
(43) Pub. Date: Apr. 15, 2021

(54) DRIVING CIRCUIT OF AN ELECTROSTATIC ADHESION BOARD AND AN ELECTROSTATIC ADHESION APPARATUS USING THE DRIVING CIRCUIT

(71) Applicant: ADVANORIGIN CO., LTD., Hsinchu City (TW)

(72) Inventor: Te-Hua Liu, Hsinchu City (TW)

(21) Appl. No.: 16/911,388

(22) Filed: Jun. 24, 2020

(30) Foreign Application Priority Data
Oct. 9, 2019 (TW) 108136482

(51) Int. Cl. H03K 3/012; H03K 5/02; H03K 3/011; H03K 3/017; H03K 17/687; H02N 13/00

(52) U.S. Cl. CPC H03K 3/012; H03K 5/02; H02N 13/00; H03K 3/017; H03K 17/687; H03K 3/011

(57) ABSTRACT

A driving circuit of electrostatic adhesion board, using a DC power source to drive an electrostatic adhesion board, comprising: a N-channel MOS power transistor having characteristics of high current and low On-resistance; a transformer having a primary winding and a secondary winding, the primary winding connected between the power supply voltage node of the DC power source and the drain node of the power transistor, accepting the potential difference between power supply voltage node of the DC power source and the power transistor as a primary voltage, the secondary winding outputting a secondary voltage which is already transformed; a voltage multiplier having an input side coupled to the secondary winding of the transformer, accepting the secondary voltage as its input voltage, then enlarging and coupling as its output voltage to the electrostatic adhesion board; a main controller connected between the power supply voltage node and a ground node of the DC power source, having a control node connected to a gate of the power transistor, controlling the adhesion force produced by the electrostatic adhesion board by controlling the on/off state of the power transistor; and a capacitor connected between the power supply voltage node and the ground node of the DC power source, stabilizing the potential difference of the DC power source.

### CROSS-REFERENCE TO RELATED APPLICATION

This application claims the priority benefit of Taiwan Application Serial No. 108136482, filed on Oct. 9, 2019. All disclosure thereof is incorporated herein by reference.

### BACKGROUND OF THE INVENTION

### A. Field of the Invention

This invention is related to a driving circuit of an electrostatic adhesion board and an electrostatic adhesion apparatus using the driving circuit, and particularly related to a compact power-saving driving circuit for a high-voltage electrostatic adhesion board and an electrostatic adhesion apparatus using the driving circuit.

### B. Description of the Prior Art

Static electricity arises from an imbalance of electric charges of an object. When an insulator approaches an electrostatically charged object, charges inside the insulator would redistribute due to the electrostatic induction caused by Coulomb force, and electrostatic adhesion occurs. Hence, the industry and so on have widely utilized the phenomena of electrostatic adhesion, performing temporary adhesion via electrostatic chuck, etc.

Besides the industrial field, in daily life, an electrostatic adhesion apparatus with an electrostatic adhesion board is used as a bulletin board or a message board. The apparatus similarly utilizes electrostatic adhesion to hold thin paper products such as business cards, bulletins, or posters.

In order to create sufficient electrostatic attraction, such an electrostatic adhesion apparatus must apply a high voltage, such as 3 KV or more, to the electrostatic adhesion board. Moreover, considering convenience of installation, the electrostatic adhesion board mostly utilizes batteries to supply power. Therefore, the electrostatic adhesion apparatus must use a driving circuit for boosting the voltage. The driving circuit boosts a voltage provided by the battery to a high voltage used by the electrostatic adhesion board.

A conventional technology is explained below by reference to FIG. 4.

In the conventional technology, the driving circuit is powered by a 6 V DC power source, which is composed of 4 dry cells in series. A main control chip IC utilizes the pull-up (PU)-pull-down (PD) circuit PUD to drive the transistor Q to vary the current, making the inductor L generate a high voltage such as 375 V or more, and utilizes a voltage octupler Vop to boost the voltage to 3 KV or more.

### SUMMARY OF THE INVENTION

The conventional technology utilizes the transistor Q in conjunction with the inductor L and the voltage octupler Vop to generate the high voltage of 3 KV or more. The transistor Q must withstand a high voltage, such as 375 V or more, and thus it is necessary to use a transistor with a rated voltage of 600-800 V. Such a high-voltage transistor Q has a higher threshold voltage Vth, and thus requires a higher power supply voltage to drive it. Therefore, the conventional technology uses a 6V DC power source.

On the other hand, mostly, the upper limit of operating voltage of a normal main control chip IC is 5.5 V. Hence, while a 6V DC power source is used, there requires a diode D1 for bucking voltage, and a capacitor C2 for stabilizing the bucked voltage.

Further, in terms of the structure, a voltage octupler Vop requires 8 capacitors and 8 diodes—numerous components.

As such, not only does the conventional technology require 4 dry cells for providing the 6V power supply voltage, but also its circuit components are numerous and have a complicated structure, which requires using high-cost surface-mounted-devices (SMD) for reducing the volume. As a result, it is hard to cut the cost.

Furthermore, the conventional technology uses an inductor to generate the high voltage. Therefore, there is no electrical isolation between the power supply circuit and the electrostatic adhesion board. In the case of high-voltage circuits, electrical leakage may easily occur, and would affect power efficiency and reliability.

Accordingly, the inventor intends to develop a driving circuit for an electrostatic adhesion board and an electrostatic adhesion apparatus using the driving circuit, so as to decrease the number of components, lessen circuit complexity, and cut cost while improving power efficiency, reducing power consumption, and being safe and reliable.

According to the disclosure, a driving circuit of an electrostatic adhesion board and an electrostatic adhesion apparatus using the driving circuit can be provided. While decreasing the number of components, lessening circuit complexity, and cutting cost, the invention can improve power efficiency and reduce power consumption.

### BRIEF DESCRIPTION OF THE DRAWINGS

FIG. 1 is a circuit diagram of an electrostatic adhesion apparatus according to one aspect of the invention.

FIG. 2 is a circuit diagram of a voltage quadrupler of an electrostatic adhesion apparatus according to one aspect of the invention.

FIG. 3 is a circuit diagram of an electrostatic adhesion apparatus according to another aspect of the invention.

FIG. 4 is a circuit diagram of an electrostatic adhesion apparatus according to a conventional technology.

### DETAILED DESCRIPTION OF THE PREFERRED EMBODIMENTS

An electrostatic adhesion apparatus of one embodiment of the invention is described below by reference to the drawings.

As illustrated in FIG. 1, in the embodiment, a DC power source 2 is used for powering the electrostatic adhesion apparatus comprised of an electrostatic adhesion board 3 and a driving circuit 1.

As illustrated in FIG. 1, the driving circuit 1 for the electrostatic adhesion board comprises: a power transistor PQ, a transformer T, a voltage quadrupler Vqp, a main controller MCU, and a capacitor C1.

The DC power source 2 comprises a power supply voltage node VCC and a ground node GND. In the embodiment, the DC power source is defined to supply a 3V DC voltage, that is, the potential difference between the power supply voltage node and the ground node GND is 3V. There is no particular requirement for the configuration of the DC power source, and any power source capable of supplying a 3V DC voltage can be used. However, considering convenience of installation, it is preferred to use batteries, for example, 2 alkaline batteries in series, to supply the power.

The electrostatic adhesion board 3 has pairs of electrodes distributed alternately and insulating layers (not showed) clad outside the electrodes.

The power transistor PQ is configured to generate a current passing through the transformer T. The power transistor is preferably an N-channel power transistor with low on-resistance, for example, NMOS (N-channel Metal Oxide-Semiconductor field-effect transistor) or IGBT (Insulated Gate Bipolar Transistor). The power transistor PQ preferably has a high current driving capability of 20 A or more, and a rated voltage of 60 V or more.

The power transistor PQ has three nodes; in the case of NMOS, it has a source node, a drain node, and a gate node, and the source node is electrically connected to the ground node GND of the DC power source 2; in the case of IGBT, it has a collector node, an emitter node, and a gate node, and the emitter is electrically connected to the ground node GND of the DC power source 2.

The transformer T has functions of voltage elevation and electrical isolation. In the embodiment, a Flyback transformer is used. The transformer T has a primary winding and a secondary winding, wherein a voltage is input on the primary winding and transformed, and a voltage is output on the secondary winding. Besides, the primary winding and the secondary winding are electrically isolated each other. Therefore, circuit safety can be improved, and electrical leakage and its side-effect can be mitigated.

As for the primary winding of the transformer T, one of the nodes is electrically connected to the power supply voltage node VCC of the DC power source 2, and the other node is electrically connected to the power transistor PQ. In other words, the transformer is electrically connected between the power supply voltage node VCC of the DC power source 2 and the power transistor PQ. Specifically, in the case of NMOS, the other node of the transformer T is electrically connected to the drain node; in the case of IGBT, the other node of the transformer T is electrically connected to the collector node.

The transformer T transforms an input primary voltage, namely the potential difference between the power supply voltage node VCC and the power transistor PQ, into an output secondary voltage.

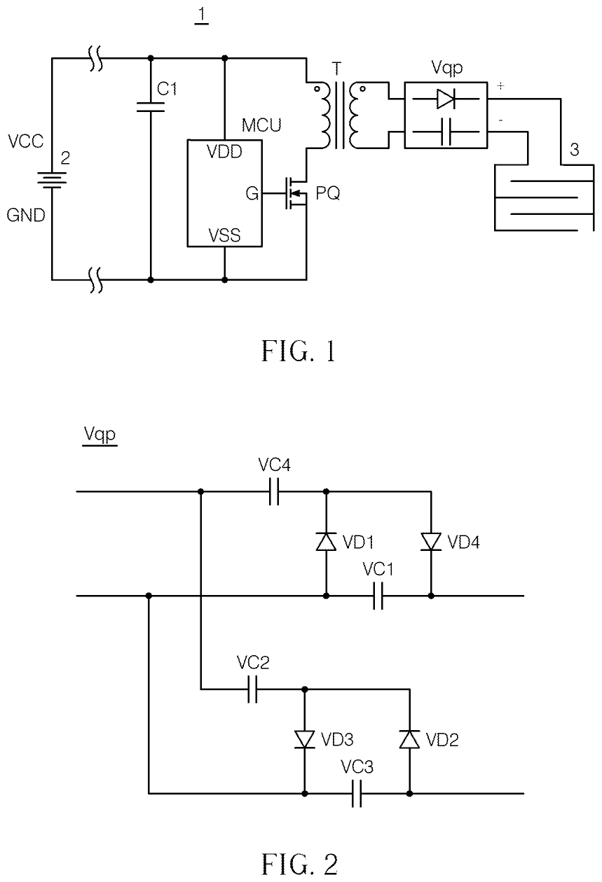

The voltage quadrupler Vqp is a voltage multiplier circuit composed of capacitors and diodes. In the embodiment, it is a voltage multiplier circuit formed through a combination of two voltage doublers. Specifically, as depicted in FIG. 2, the voltage quadrupler Vqp of the embodiment is formed by a combination of two Greinacher circuits having opposite polarities, and has capacitors VC1-VC4 and diodes VD1-VD4. The diodes preferably have rated voltages of 4 KV or more. The capacitors preferably have rated voltages of 3 KV or more and can have, for example, capacitance of 470 pf.

The input side of the voltage quadrupler Vqp is electrically connected to the secondary winding of the transformer T, and the output side of the voltage quadrupler Vqp is electrically connected to the electrostatic adhesion board 3. In other words, the secondary voltage of the transformer T is input to two nodes on the input side of the voltage quadrupler Vqp, and is boosted to a fourfold voltage and output, from two nodes on the output side, to the electrostatic adhesion board 3. In the embodiment, the secondary voltage output by the transformer T is about 800 V, and thus the input voltage of the voltage quadrupler Vqp is also about 800 V and its output voltage is about 3.2 KV.

The main controller MCU is a microcontroller, which has a power source input node VDD, a power source ground node VSS, and a control node G The main controller MCU is electrically connected to the DC power source 2 and the power transistor PQ. Specifically, the power source input node VDD of the main controller MCU is electrically connected to the power supply voltage node VCC of the DC power source 2; the power source ground node VSS is electrically connected to the ground node GND of the DC power source 2; the control node G is electrically connected to the gate node of the power transistor PQ.

The main controller MCU outputs a signal at the control node G, thereby driving the power transistor PQ. Specifically, the main controller MCU outputs a square wave at the control node G, making the power transistor PQ consecutively switch between on-state and off-state.

The capacitor C1 is electrically connected to the DC power source 2, so as to stabilize the voltage supplied by the DC power source 2. Specifically, the capacitor C1 is electrically connected between the power supply voltage node VCC and the ground node GND of the DC power source 2, so as to stabilize the potential difference between the power supply voltage node VCC and the ground node GND.

When the driving circuit 1 for the electrostatic adhesion board is electrically connected to the DC power source 2, the main controller MCU receives power supplied from the DC power source 2 so as to operate, thereby outputting, at the control node G, a square-wave signal to the gate node of the power transistor PQ and turning the power transistor PQ on or off. A varying current flows through the primary winding of the transformer T. A secondary voltage is output after transformation of the transformer T, and is boosted fourfold by the voltage quadrupler Vqp and output to the electrostatic adhesion board 3, thereby generating electrostatic adhesion force.

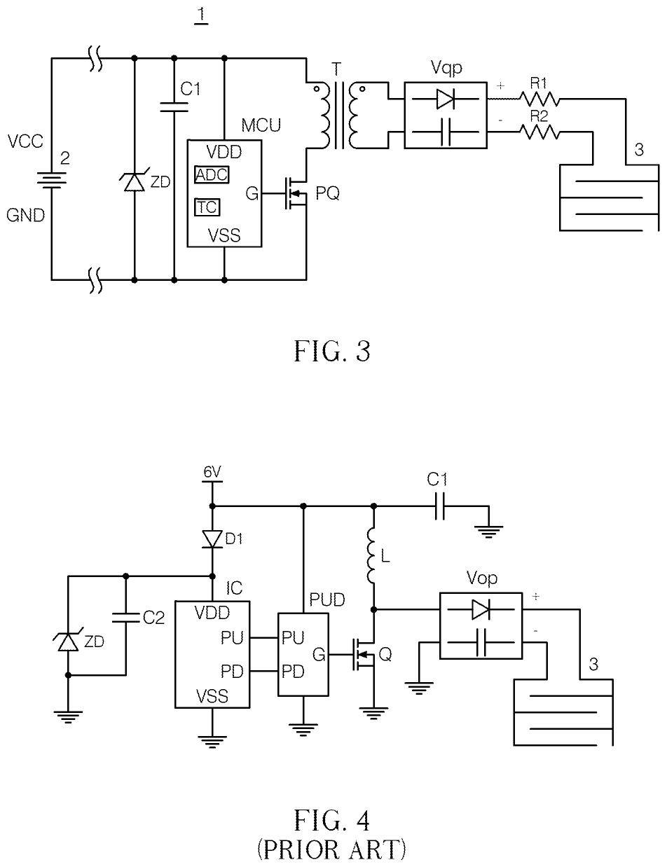

Alternatively, the driving circuit 1 for an electrostatic adhesion board may be as shown in FIG. 3, wherein the driving circuit 1 further comprises a Zener diode ZD electrically connected to the DC power source 2 for avoiding high voltage caused by electrical leakage on the primary winding of the transformer T. Specifically, the cathode node of the Zener diode ZD is electrically connected to the power supply voltage node VCC of the DC power source 2, and the anode node is electrically connected to the ground node GND of the DC power source 2. In other words, the Zener diode ZD is connected in parallel to the capacitor C1. In the embodiment, the Zener voltage of the Zener diode is preferably 5.5 V-6.8 V.

Also, the main controller MCU can further comprises: an analog-to-digital converting circuit ADC for measuring the voltage of the DC power source 2. As the voltage of the battery power source 2 drops over time, it is possible that the driving circuit 1 for the electrostatic adhesion board cannot output a sufficiently high voltage, thus reducing electrostatic adhesion force of the electrostatic adhesion board 3.

In response to this, the main controller MCU can alter frequency and/or duty cycle of the square wave output by the control node G according to measurement of the analogy-to-digital converting circuit ADC to adjust the average output current and voltage of the transformer T, thereby stabilizing the high voltage output by the driving circuit 1 for the electrostatic adhesion board and maintain the electrostatic adhesion force of the electrostatic adhesion board 3. In the disclosure, the phrases “frequency and/or duty cycle” or “at least one of frequency and duty cycle” should be understood to mean “only frequency”, “only duty cycle”, or “both frequency and duty cycle”.

Furthermore, the main controller MCU can also comprise a temperature indicator TC.

When the ambient temperature rises, electrical leakage from the electrostatic adhesion board 3 and the driving circuit 1 for the electrostatic adhesion board may increase, which reduces electrostatic adhesion force of the electrostatic adhesion board 3.

In response to this, the MCU can alter the frequency and/or duty cycle of the square wave output by the control node G according to detection of the temperature indicator TC to adjust the average output current and voltage of the transformer T, thereby compensating for the electrical leakage due to temperature and maintain the electrostatic adhesion force of the electrostatic adhesion board 3.

On the other hand, when the ambient temperature drops, electrical leakage decreases. The MCU can alter the frequency and/or duty cycle of the control node G to reduce power consumption.

Additionally, the driving circuit 1 for the electrostatic adhesion board can further comprise buffer resistors R1 and R2 interposed between the voltage quadrupler Vqp and the electrostatic adhesion board 3 to limit the current from the voltage quadrupler Vqp. Specifically, the buffer resistors R1 and R2 are respectively placed at the two nodes of the output side of the voltage quadrupler Vqp. In other words, the buffer resistor R1, the electrostatic adhesion board 3, and the buffer resistor R2 are sequentially connected in series. For example, the buffer resistors R1, R2 can be 10 MΩ.

The driving circuit 1 for the electrostatic adhesion board in the embodiment has an average current 0.11 mA. If two alkaline batteries of 1200 mAh serve as the DC power source, it can last about 454 days. In comparison, in the case of the conventional technology, the battery can last about 270 days, and needs twofold dry cells. Therefore, compared to the conventional technology, the embodiment has a 3.36 times of power efficiency, and has an excellent performance.

What is claimed is:

1. A driving circuit for an electrostatic adhesion board, the driving circuit using a DC power source to drive the electrostatic adhesion board, the driving circuit comprising:
an N-channel MOS power transistor having high current capability and low on-resistance, a source node of the power transistor electrically connected to a ground node of the DC power source;
a transformer, a primary winding of the transformer electrically connected between a power supply voltage node of the DC power source and a drain node of the power transistor, a potential difference between the power supply voltage node and the drain node serving as a primary voltage of the transformer, a secondary winding of the transformer outputting a secondary voltage after transformation;
a voltage multiplier, an input side of the voltage multiplier coupled to the secondary winding of the transformer and receiving the secondary voltage as an input voltage, the voltage multiplier outputting to the electrostatic adhesion board a voltage which is generated by amplifying the input voltage;
a main controller, electrically connected between the power supply voltage node and the ground node, a control node of the main controller electrically connected to a gate node of the power transistor and outputting a square wave for controlling on/off state of the power transistor so as to control an adhesion force generated by the electrostatic adhesion board; and
a capacitor, electrically connected between the power supply voltage node and the ground node so as to stabilize a potential difference of the DC power source.

2. The driving circuit of claim 1, further comprising:
a Zener diode, electrically connected between the power supply voltage node and the ground node of the DC power source.

3. The driving circuit of claim 1, further comprising:
a first resistor and a second resistor, first nodes of the first resistor and the second resistor electrically connected to a positive output node and a negative output node of the voltage multiplier respectively, second nodes of the first resistor and the second resistor electrically connected to the electrostatic adhesion board.

4. The driving circuit of claim 1, further comprising:
a Zener diode, electrically connected between the power supply voltage node and the ground node of the DC power source; and
a first resistor and a second resistor, first nodes of the first resistor and the second resistor electrically connected to a positive output node and a negative output node of the voltage multiplier respectively, second nodes of the first resistor and the second resistor electrically connected to the electrostatic adhesion board.

5. The driving circuit of claim 1, wherein,
the main controller measures a temperature or a voltage of the DC power source and, in response to the measurement, adjusts at least one of frequency and duty cycle of the square wave output by the control node so as to adjust adhesion force generated by the electrostatic adhesion board.

6. An electrostatic adhesion apparatus, comprising:
a driving circuit for an electrostatic adhesion board according to claim 1, and
the electrostatic adhesion board.

7. A driving circuit for an electrostatic adhesion board, the driving circuit using a DC power source to drive the electrostatic adhesion board, the driving circuit comprising:
an N-channel IGBT power transistor having high current capability and low on-resistance, an emitter node of the power transistor electrically connected to a ground node of the DC power source;
a transformer, a primary winding of the transformer electrically connected between a power supply voltage node of the DC power source and a collector node of the power transistor, a potential difference between the power supply voltage node and the collector node serving as a primary voltage of the transformer, a secondary winding of the transformer outputting a secondary voltage after transformation;
a voltage multiplier, an input side of the voltage multiplier coupled to the secondary winding of the transformer and receiving the secondary voltage as an input voltage, the voltage multiplier outputting to the electrostatic adhesion board a voltage which is generated by amplifying the input voltage;
a main controller, electrically connected between the power supply voltage node and the ground node, a control node of the main controller electrically connected to a gate node of the power transistor and outputting a square wave for controlling on/off state of the power transistor so as to control an adhesion force generated by the electrostatic adhesion board; and
a capacitor, electrically connected between the power supply voltage node and the ground node so as to stabilize a potential difference of the DC power source.

8. The driving circuit of claim 7, further comprising:
a Zener diode, electrically connected between the power supply voltage node and the ground node of the DC power source.

9. The driving circuit of claim 7, further comprising:
a first resistor and a second resistor, first nodes of the first resistor and the second resistor electrically connected to a positive output node and a negative output node of the voltage multiplier respectively, second nodes of the first resistor and the second resistor electrically connected to the electrostatic adhesion board.

10. The driving circuit of claim 7, further comprising:
a Zener diode, electrically connected between the power supply voltage node and the ground node of the DC power source; and
a first resistor and a second resistor, first nodes of the first resistor and the second resistor electrically connected to a positive output node and a negative output node of the voltage multiplier respectively, second nodes of the first resistor and the second resistor electrically connected to the electrostatic adhesion board.

11. The driving circuit of claim 7, wherein,
the main controller measures a temperature or a voltage of the DC power source and, in response to the measurement, adjusts at least one of frequency and duty cycle of the square wave output by the control node so as to adjust adhesion force generated by the electrostatic adhesion board.

12. An electrostatic adhesion apparatus, comprising:
a driving circuit for an electrostatic adhesion board according to claim 7, and
the electrostatic adhesion board.
